(19) United States
(12) Patent Application Publication
(10) Pub. No.: US 2024/0003359 A1
(43) Pub. Date: Jan. 4, 2024

(54) THINNED PUMP

(71) Applicant: COOLER MASTER CO., LTD., Taipei City (TW)

(72) Inventors: Chiu Yu YEH, Taipei City (TW); Wen-Hsien LIN, Taipei City (TW); Chia-Hao SUNG, Taipei City (TW); Wen-Hung CHEN, Taipei City (TW)

(73) Assignee: COOLER MASTER CO., LTD., Taipei City (TW)

(21) Appl. No.: 18/101,039

(22) Filed: Jan. 24, 2023

(30) Foreign Application Priority Data
Jul. 1, 2022 (TW) 111124768

(51) Int. Cl. F04D 29/42; F04D 25/06

(52) U.S. Cl. CPC F04D 29/4206; F04D 25/0693

(57) ABSTRACT

A thinned pump includes a casing, a rotor assembly and a stator assembly. The casing includes a base and a cover. The cover covers the base so as to form a fluid chamber together, the cover has an inlet channel and an outlet channel, and the inlet channel and the outlet channel are in fluid communication with the fluid chamber. The rotor assembly includes an impeller and a magnetic component. The impeller is rotatably disposed in the casing, and the magnetic component is embedded into the impeller. The stator assembly includes a plurality of magnetically conductive pillars and a plurality of coils. The magnetically conductive pillars are mounted at one side of the base located opposite to the fluid chamber, and the coils are respectively disposed on the magnetically conductive pillars.

### CROSS-REFERENCE TO RELATED APPLICATIONS

This non-provisional application claims priority under 35 U.S.C. § 119(a) on Patent Application No(s). 111124768 filed in Taiwan, R.O.C. on Jul. 1, 2022, the entire contents of which are hereby incorporated by reference.

### TECHNICAL FIELD

The disclosure relates to a pump, more particularly to a thinned pump.

### BACKGROUND

As the performances of electronic devices enhanced, huge amount of heat may be generated by electronic components in the electronic devices during operation. In order to prevent the temperature of the electronic component from exceeding endurable temperature, heat dissipation fin assembly may be provided on the electronic component to take away heat generated by the electronic component. However, heat dissipation fin assembly has its limit to dissipate heat, and thus some manufacturers replace the heat dissipation fin assembly with a liquid cooling system capable of dissipating heat of the electronic component more efficiently. The liquid cooling system generally includes a radiator, a cold plate and a pump. The radiator, the cold plate and the pump are in fluid communication with one another so as to form a loop of a working fluid, and the pump can drive the working fluid to flow through the cold plate and the radiator and then flow back to the pump. The cold plate is mounted on a heat source, such as a processor, and the cold plate can absorb heat generated by the heat source and transferred to the working fluid. When the working fluid flows to the radiator, the radiator can dissipate heat of the working fluid.

Since the electronic devices are required to be lightweight, thin and small, how to further reduce the thickness of the pump is one of the crucial topics in this field.

### SUMMARY

The disclosure provides to a thinned pump whose thickness is further reduced.

One embodiment of the disclosure provides a thinned pump. The thinned pump includes a casing, a rotor assembly and a stator assembly. The casing includes a base and a cover. The cover covers the base so as to form a fluid chamber together, the cover has an inlet channel and an outlet channel, and the inlet channel and the outlet channel are in fluid communication with the fluid chamber. The rotor assembly includes an impeller and a magnetic component. The impeller is rotatably disposed in the casing, and the magnetic component is embedded into the impeller. The stator assembly includes a plurality of magnetically conductive pillars and a plurality of coils. The magnetically conductive pillars are mounted at one side of the base located opposite to the fluid chamber, and the coils are respectively disposed on the magnetically conductive pillars.

According to the thinned pump as disclosed in the above embodiment, the magnetic component of the thinned pump is embedded into the impeller, such that the overall thickness of the rotor assembly can be reduced so as to achieve the slimness of the thinned pump. Moreover, the stator assembly includes the magnetically conductive pillars instead of conventional stator yokes, and the magnetically conductive pillars are welded to the circuit board, such that the thinned pump can be further slimmed.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of a thinned pump according to one embodiment of the disclosure;

FIG. 2 is an exploded view of the thinned pump in FIG. 1;

FIG. 3 is another exploded view of the thinned pump in FIG. 1; and

FIG. 4 is a cross-sectional view of the thinned pump in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

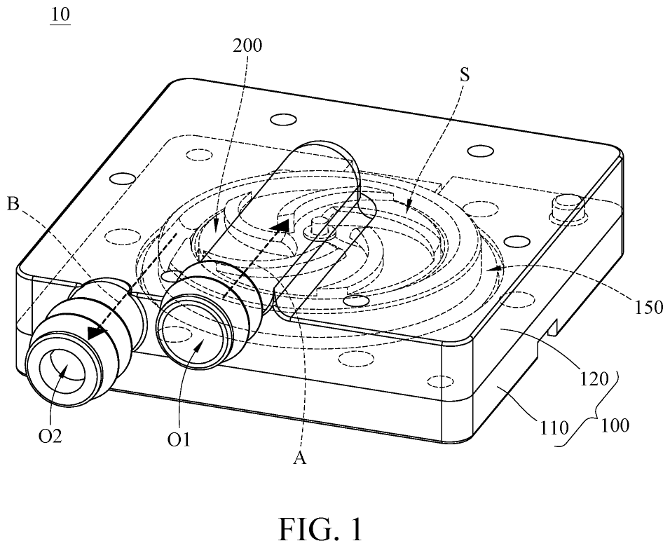

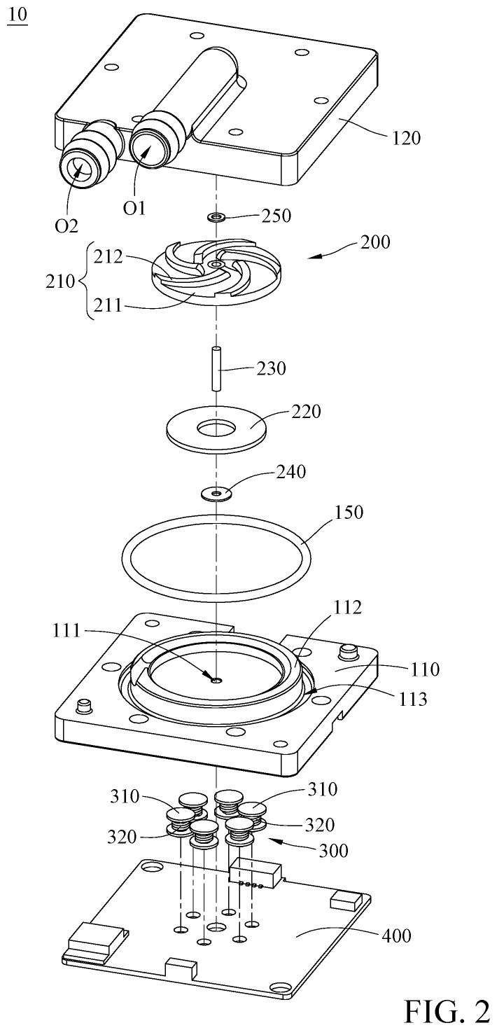

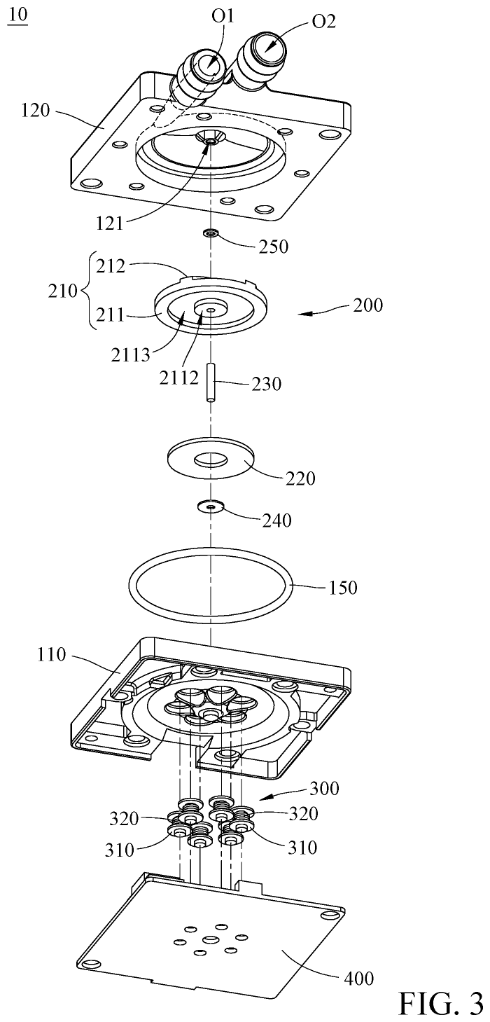

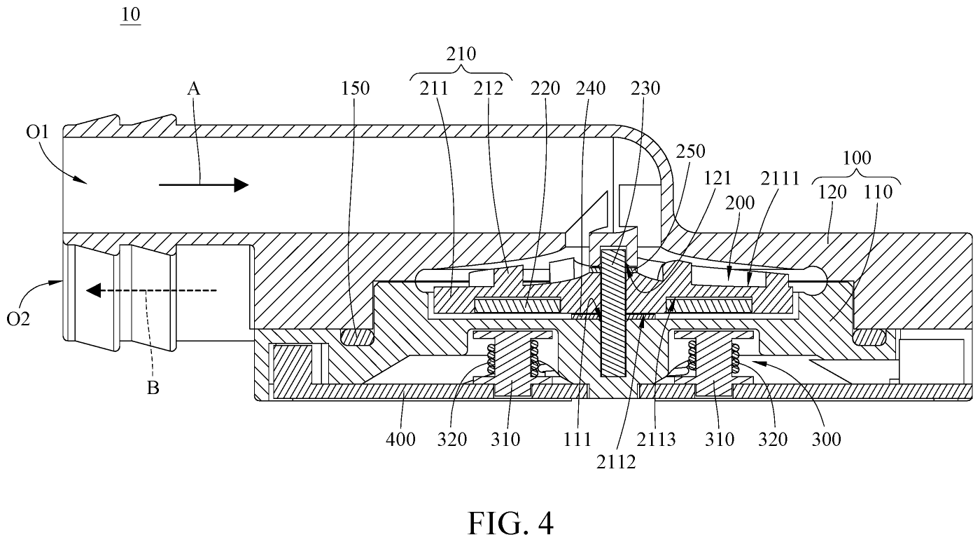

Refer to FIGS. 1 to 4. FIG. 1 is a perspective view of a thinned pump according to one embodiment of the disclosure, FIG. 2 is an exploded view of the thinned pump in FIG. 1, FIG. 3 is another exploded view of the thinned pump in FIG. 1, and FIG. 4 is a cross-sectional view of the thinned pump in FIG. 1.

In this embodiment, the thinned pump 10 is configured to be connected to a radiator or a cold plate, and the thinned pump 10 can drive a working fluid to flow through the radiator and the cold plate and return to the thinned pump 10 so as to complete a circulation of the work fluid. The thinned pump 10 includes a casing 100, a rotor assembly 200 and a stator assembly 300. The thinned pump 10 may further include a circuit board 400.

The casing 100 includes a base 110 and a cover 120. The cover 120 covers the base 110 so as to form a fluid chamber S together. The cover 120 has an inlet channel O1 and an outlet channel O2. In this embodiment, the inlet channel O1 is connected to a center of the fluid chamber S. The outlet channel O2 is connected to a periphery of the fluid chamber S. Specifically, the outlet channel O2 is, for example, connected to the fluid chamber S along a tangent line of the fluid chamber S.

The rotor assembly 200 includes an impeller 210 and a magnetic component 220. The impeller 210 is rotatably disposed in the casing 100. The magnetic component 220 is a permanent magnet and is embedded in the impeller 210. Specifically, the impeller 210 includes a base portion 211 and a plurality of blade portions 212. The base portion 211 has a first surface 2111, a second surface 2112 and a recess 2113. The second surface 2112 faces away from the first surface 2111, and the recess 2113 is located at the second surface 2112. The blade portions 212 protrude from the first surface 2111. The magnetic component 220 is integrally disposed in the recess 2113 of the base portion 211 via, for example, an embedding or overmolding process.

In this embodiment, the rotor assembly 200 may further include a shaft 230, a first abrasion-resistance washer 240 and a second abrasion-resistance washer 250. The base 110 has a shaft hole 111, and the cover 120 has a shaft hole 121. Two opposite ends of the shaft 230 are respectively inserted into the shaft hole 111 of the base 110 and the shaft hole 121 of the cover 120. The first abrasion-resistance washer 240 is located between the impeller 210 and the base 110, and the second abrasion-resistance washer 250 is located between the impeller 210 and the cover 120. A hardness of the first abrasion-resistance washer 240 and a hardness of the second abrasion-resistance washer 250 are greater than a hardness of the base 110 and a hardness of the cover 120. As a result, the first abrasion-resistance washer 240 and the second abrasion-resistance washer 250 can reduce the abrasions of the base 110 and the cover 120 by the impeller 210.

In this embodiment, the shaft 230 and the impeller 210 are made of two separate pieces, but the disclosure is not limited thereto; in some other embodiments, the shaft and the impeller may be integrally made of one single piece.

In this embodiment, the base 110 has an annular protrusion 112, and the annular protrusion 112 is in contact with the cover 120 and surrounds the fluid chamber S. In addition, the thinned pump 10 may further include a sealing ring 150. The base 110 further has an annular recess 113, and the annular recess 113 is located farther away from the shaft hole 111 of the base 110 than the annular protrusion 112. The sealing ring 150 is disposed in the annular recess 113 and clamped between the base 110 and the cover 120. As a result, the annular protrusion 112 and/or the sealing ring 150 can increase the sealing of the fluid chamber S.

The circuit board 400 is mounted at one side of the base 110 located opposite to the fluid chamber S. The stator assembly 300 includes a plurality of magnetically conductive pillars 310 and a plurality of coils 320. The magnetically conductive pillars 310 are, for example, welded to the circuit board 400, and the magnetically conductive pillars 310 are located at one side of the base 110 located opposite to the fluid chamber S. The coils 320 are respectively disposed on the magnetically conductive pillars 310. The stator assembly 300 and the magnetic component 220 of the rotor assembly 200 interact with each other so as to drive the rotor assembly 200 to rotate relative to the casing 100.

In this embodiment, the magnetically conductive pillars 310 are welded to the circuit board 400 so as to be fixed to the circuit board 400, but the disclosure is not limited thereto; in some other embodiments, the magnetically conductive pillars may be fixed to the circuit board via adhesive or a snap-fit means.

In this embodiment, the work fluid flows into the inlet channel O1 along a direction A, and then flows into the center of the fluid chamber S from the top of the fluid chamber S via the guidance of the inlet channel O1. Then, the rotation of the impeller 210 drives the working fluid to flow towards the periphery of the fluid chamber S, such that the working fluid flows out of the fluid chamber S from the outlet channel O2 along a direction B. In this embodiment, the magnetic component 220 of the thinned pump 10 is embedded into the impeller 210, such that the overall thickness of the rotor assembly 200 can be reduced so as to achieve the slimness of the thinned pump 10. Moreover, the stator assembly 300 includes the magnetically conductive pillars 310 instead of conventional stator yokes, and the magnetically conductive pillars 310 are welded to the circuit board 400, such that the thinned pump 10 can be further slimmed.

According to the thinned pump as disclosed in the above embodiment, the magnetic component of the thinned pump is embedded into the impeller, such that the overall thickness of the rotor assembly can be reduced so as to achieve the slimness of the thinned pump. Moreover, the stator assembly includes the magnetically conductive pillars instead of conventional stator yokes, and the magnetically conductive pillars are welded to the circuit board, such that the thinned pump can be further slimmed.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A thinned pump, comprising:
a casing, comprising a base and a cover, wherein the cover covers the base so as to form a fluid chamber together, the cover has an inlet channel and an outlet channel, and the inlet channel and the outlet channel are in fluid communication with the fluid chamber;
a rotor assembly, comprising an impeller and a magnetic component, wherein the impeller is rotatably disposed in the casing, and the magnetic component is embedded into the impeller; and
a stator assembly, comprising a plurality of magnetically conductive pillars and a plurality of coils, wherein the plurality of magnetically conductive pillars are mounted at one side of the base located opposite to the fluid chamber, and the plurality of coils are respectively disposed on the plurality of magnetically conductive pillars.

2. The thinned pump according to claim 1, further comprising a circuit board, wherein the circuit board is mounted at one side of the base located opposite to the fluid chamber, and the plurality of magnetically conductive pillars are welded to the circuit board.

3. The thinned pump according to claim 1, wherein the inlet channel is connected to a center of the fluid chamber, and the outlet channel is connected to a periphery of the fluid chamber.

4. The thinned pump according to claim 1, wherein the impeller comprises a base portion and a plurality of blade portions, the base portion has a first surface, a second surface and a recess, the second surface faces away from the first surface, the recess is located at the second surface, the plurality of blade portions protrude from the first surface, and the magnetic component is disposed in the recess.

5. The thinned pump according to claim 4, wherein the magnetic component is disposed in the recess of the base portion via an embedding or overmolding process.

6. The thinned pump according to claim 1, wherein the rotor assembly further comprises a shaft, each of the base and the cover has a shaft hole, and two opposite ends of the shaft are respectively inserted into the shaft hole of the base and the shaft hole of the cover.

7. The thinned pump according to claim 6, wherein the rotor assembly further comprises a first abrasion-resistance washer and a second abrasion-resistance washer, the first abrasion-resistance washer is located between the impeller and the base, and the second abrasion-resistance washer is located between the impeller and the cover.

8. The thinned pump according to claim 6, wherein the base has an annular protrusion, and the annular protrusion is in contact with the cover and surrounds the fluid chamber.

9. The thinned pump according to claim 8, further comprising a sealing ring, wherein the base has an annular recess, the annular recess is located farther away from the shaft hole of the base than the annular protrusion, and the sealing ring is disposed in the annular recess and clamped between the base and the cover.
